(19) United States
(12) Patent Application Publication
(10) Pub. No.: US 2023/0185993 A1
(43) Pub. Date: Jun. 15, 2023

(54) CONFIGURABLE SIMULATION TEST SCENARIOS FOR AUTONOMOUS VEHICLES

(71) Applicant: GM Cruise Holdings LLC, San Francisco, CA (US)

(72) Inventors: Caleb Johnson, Oakland, CA (US); Thomas Busser, San Francisco, CA (US); Casey Weaver, San Francisco, CA (US)

(21) Appl. No.: 17/550,224

(22) Filed: Dec. 14, 2021

(51) Int. Cl. G06F 30/23; G06T 19/00; G05B 13/04

(52) U.S. Cl. CPC G06F 30/23; G06T 19/003; G05B 13/048

(57) ABSTRACT

The disclosed technology provides solutions for improving simulation environments. In some aspects, a processor may be configured to select one or more location properties associated with a simulated road environment for testing an action of an autonomous vehicle. In some cases, the processor may identify a plurality of geographic locations having the one or more location properties associated with the simulated road environment. In some examples, the processor may generate the simulated road environment using map data associated with a first geographic location selected from the plurality of geographic locations. In some aspects, the processor may test the action of the autonomous vehicle using the simulated road environment.

### BACKGROUND

### 1. Technical Field

The disclosed technology provides solutions for improving simulation environments and in particular, the disclosed technology provides configurable simulation test scenarios for autonomous vehicles.

### 2. Introduction

An autonomous vehicle is a motorized vehicle that can navigate without a human driver. An example autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system.

In some cases, an autonomous vehicle may implement one or more machine learning algorithms for perceiving the environment, predicting the future trajectory of objects in the environment, and/or operating the autonomous vehicle. As such, an autonomous vehicle will need to perform many of the functions that are conventionally performed by human drivers, such as performing navigation and routing tasks necessary to provide a safe and efficient transportation. Such tasks may be improved by providing simulated environments that can be used to test the software of the autonomous vehicle.

### BRIEF DESCRIPTION OF THE DRAWINGS

Certain features of the subject technology are set forth in the appended claims. However, the accompanying drawings, which are included to provide further understanding, illustrate disclosed aspects and together with the description serve to explain the principles of the subject technology. In the drawings:

FIG. 1 illustrates an example of a system for managing one or more Autonomous Vehicles (AVs), in accordance with some aspects of the present technology.

FIG. 2 illustrates an example system for simulating the operation of an autonomous vehicle, in accordance with some aspects of the present technology.

FIG. 3 illustrates an example test scenario within a simulation environment, in accordance with some aspects of the present technology.

FIG. 4 illustrates another example test scenario within a simulation environment, in accordance with some aspects of the present technology.

FIG. 5 illustrates a block diagram of an example process for implementing configurable test scenarios for autonomous vehicles, in accordance with some aspects of the present technology.

FIG. 6 illustrates an example processor-based system with which some aspects of the subject technology can be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One way to improve various aspects of autonomous vehicle (AV) performance, such as navigation and routing functions, is to simulate AV operations for various driving scenarios. The simulation of such scenarios can be performed in a virtual environment, such as a three-dimensional (3D) virtual environment that can be used to generate synthetic AV sensor data that replicates real-world environments.

In some cases, implementing test scenarios in a virtual environment can be tedious and time-consuming because the test scenario is not easily modified. For instance, an operator may have to manually configure or select a particular intersection that is suitable for conducting an intended test such as an unprotected left turn. In some cases, the test scenario cannot be moved from one geographic location to another, which can necessitate implementation of a new test scenario.

In some examples, test scenarios are not easily configured for conducting intended tests or maneuvers. For instance, an operator may design a test scenario that is intended to test a particular maneuver, but the autonomous vehicle may circumvent the intended test (e.g., take a different route). In some cases, the operator will have to redesign the test scenario to attempt to elicit the intended test. In some examples, the simulation system may not have the capability to determine that the autonomous vehicle did not perform the intended test, which can further hamper software development and testing.

The disclosed technology addresses a need in the art for providing a simulation environment that implements configurable simulation test scenarios. Aspects of the disclosed technology address the foregoing need by providing solutions for configuring test scenarios that may be adapted or reused with different parameters (e.g., different geographic locations). In some approaches, the disclosed technology provides a novel process for encoding intent instructions (e.g., test intent) for an autonomous vehicle simulation system.

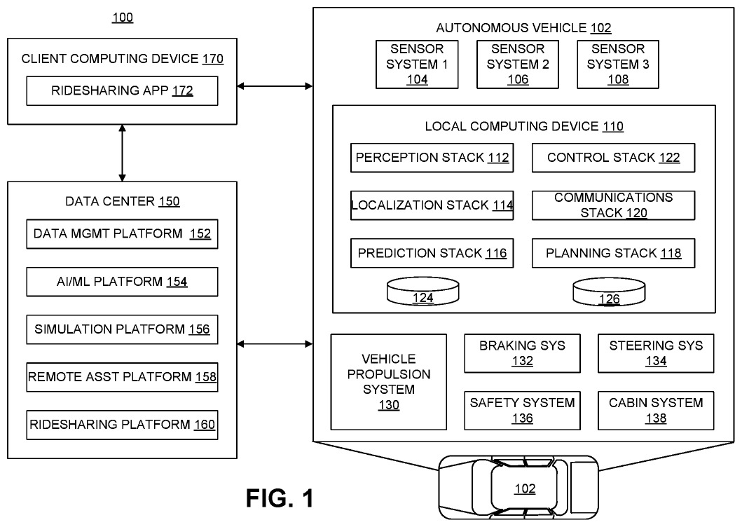

FIG. 1 illustrates an example of an AV management system 100. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by multiple sensor systems 104, 106, and 108. The sensor systems 104-108 can include different types of sensors and can be arranged about the AV 102. For instance, the sensor systems 104-108 can comprise Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other embodiments may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some embodiments, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can additionally include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can also identify environmental uncertainties, such as where to look for moving objects, flag areas that may be obscured or blocked from view, and so forth. In some embodiments, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LIDAR, RADAR, ultrasonic sensors, the HD geospatial database 126, etc.). For example, in some embodiments, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some embodiments, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some embodiments, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structured (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system, including a server, desktop computer, laptop, tablet, smartphone, smart wearable device (e.g., smartwatch, smart eyeglasses or other Head-Mounted Display (HMD), smart ear pods, or other smart in-ear, on-ear, or over-ear device, etc.), gaming system, or other general purpose computing device for accessing the ridesharing application 172. The client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

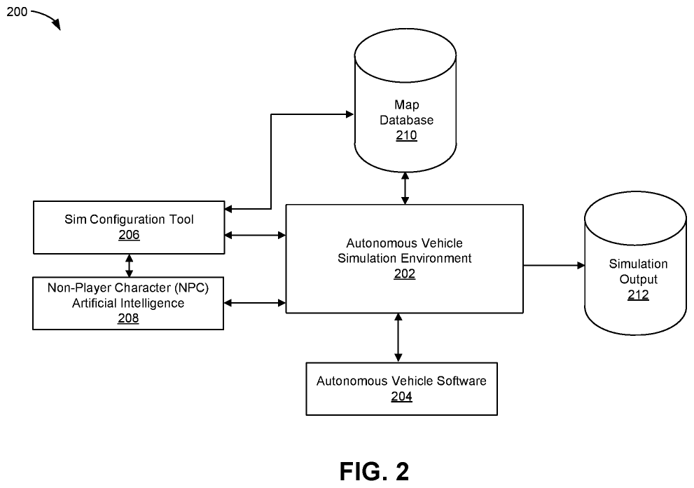

FIG. 2 illustrates an example system 200 for simulating the operation of an autonomous vehicle. In some aspects, system 200 can correspond to one or more components associated with AI/ML platform 154 and/or simulation platform 156. In some embodiments, system 200 can include autonomous vehicle (AV) simulation environment 202. In some cases, AV simulation environment 202 can be used to simulate and test the operation of AV software 204. For example, AV simulation environment 202 can be used to replicate scenarios that may be encountered by an AV (e.g., AV 102) in a real-world environment.

In some embodiments, AV simulation environment 202 can be configured to perform one or more simulated test scenarios using sim configuration tool 206. In some cases, a simulated test scenario can include configurable intent instructions that describe the intended test for the autonomous vehicle and/or for other agents or entities within the simulated environment. In some aspects, the test can include any action or maneuver that may be performed by a vehicle as driven by a human. For example, the test can include making a right turn at a stop sign, making a left turn at a stop sign, making a right turn at a red traffic light, making an unprotected left turn (e.g., oncoming traffic not obliged to stop), changing lanes, navigating road construction, navigating around an accident, navigating around a double-parked vehicle, parallel parking, etc. The foregoing list provides some examples of tests that may be performed using AV simulation environment 202. Those skilled in the art will recognize that the present technology can be used to implement these and/or any other tests suitable for an autonomous vehicle.

In some aspects, sim configuration tool 206 can be used to configure one or more layers (e.g., variables, parameters, etc.) associated with AV simulation environment 202. For instance, sim configuration tool 206 can be used to configure or select location properties associated with a location for performing a test. In some examples, location properties can include a number of traffic lanes, a traffic signal, a stop sign, a yield sign, a speed limit, a turning lane, a cross street, a bicycle lane, a crosswalk, a street slope, a street curve, any other location property, and/or any combination thereof. For example, sim configuration tool 206 can be used to implement a test in which the autonomous vehicle makes a left turn at an intersection that does not have a traffic light, with no turning lane, a single lane of traffic in both directions, and a cross street with 2 lanes of traffic.

In some embodiments, sim configuration tool 206 can communicate with map database 210 to identify one or more geographic locations that have the selected location properties. For instance, map data obtained from map database 210 can be used by sim configuration tool 206 to identify one or more intersections within a selected city (e.g., San Francisco) that have the location properties associated with the intended test. In some examples, sim configuration tool 206 can use map database 210 to identify geographic locations throughout the world that can be used to conduct the simulated test.

In some cases, sim configuration tool 206 can be used to configure additional layers associated with AV simulation environment 202. For example, sim configuration tool 206 can be used to configure the placement and/or attributes of one or more non-player characters (NPCs) within the AV simulation environment 202. In some cases, an NPC can include pedestrians, cyclists, vehicles, ambulances, buses, cable cars, trains, motorcycles, mopeds, animals, and/or any other entity or agent that may be present within AV simulation environment 202. In some aspects, sim configuration tool 206 can be used to configure the placement of NPCs and/or the composition of the simulated scene. For example, sim configuration tool 206 can be used to configure types of NPCs used in the simulated test (e.g., bus, sedan, motorcycle, etc.).

In some instances, sim configuration tool 206 can be used to configure different start positions for different NPCs (e.g., variable NPC placement for different test scenarios). In some cases, sim configuration tool 206 may be used to configure intent instructions associated with NPCs. For example, sim configuration tool 206 can include an intent instruction for a pedestrian to enter a crosswalk that is in the path of the autonomous vehicle.

In some embodiments, sim configuration tool 206 may be configured to interface with NPC Artificial Intelligence (AI) 208. In some cases, NPC AI 208 can be used to control one or more NPCs within AV simulation environment 202. In some cases, NPC AI 208 can control the operation (e.g., position, movement, etc.) of pedestrians, vehicles, animals, and/or any other NPC within AV simulation environment 202. In some aspects, NPC AI 208 may control one or more NPCs within AV simulation environment 202 based on the intent instructions and/or parameterization received from sim configuration tool 206. For example, NPC AI 208 may control the movement of an NPC vehicle based on an intent instruction configuring the NPC vehicle to abruptly block an AV having the right of way (e.g., testing AV accident avoidance).

In some aspects, sim configuration tool 206 can be used to configure layers within AV simulation environment 202 corresponding to traffic flow. For example, sim configuration tool 206 can be used to implement a temporary road closure (e.g., due to road construction or a traffic accident). In some cases, sim configuration tool 206 can be used to configure layers within AV simulation environment 202 relating to weather (e.g., fog, rain, snow, hail, flooding, smoke, etc.), road conditions (e.g., dry, iced, snow-covered, wet, sandy, potholes, etc.), time of day (e.g., day, night, sunrise, sunset, etc.), and/or any other suitable parameter for implementing AV testing within AV simulation environment 202.

In some examples, sim configuration tool 206 can be configured to determine whether a simulated test scenario executed properly (e.g., based on design intent). For example, sim configuration tool 206 can be configured to interface with AV software 204 to determine whether the AV performed an intended maneuver. In some aspects, sim configuration tool 206 may receive a signal from planning stack 118 indicating that the AV will perform the intended test maneuver (e.g., planning stack indicates that AV will make a left turn). In some cases, sim configuration tool 206 may determine whether an NPC within a test scenario performed its intended function. For instance, sim configuration tool 206 may check the location of an NPC at the conclusion of a simulated test scenario to determine whether test executed as intended. In one illustrative example, sim configuration tool 206 may confirm that a pedestrian NPC is on the opposite side of a street (e.g., crossed the street) relative to a start position of the pedestrian NPC.

In some cases, sim configuration tool 206 can be used to adapt or reconfigure test scenarios. As noted above, sim configuration tool 206 can be used to find multiple geographic locations having location properties for executing a simulated test. In some aspects, sim configuration tool 206 can be used to modify any parameter or layer associated with AV simulation environment 202 in order to run multiple variations of a simulated test without creating a new test scenario.

In some examples, AV simulation environment 202 may store simulation data (e.g., test scenarios, layers, parameters, functions, etc.) in a database such as simulation output 212. In some cases, simulation output 212 can be used to query a world state (e.g., state of all simulation parameters) within AV simulation environment 202 at any time associated with a simulation. In some aspects, simulation output 212 can be used to retrieve test scenarios for re-running simulations and/or variations thereof.

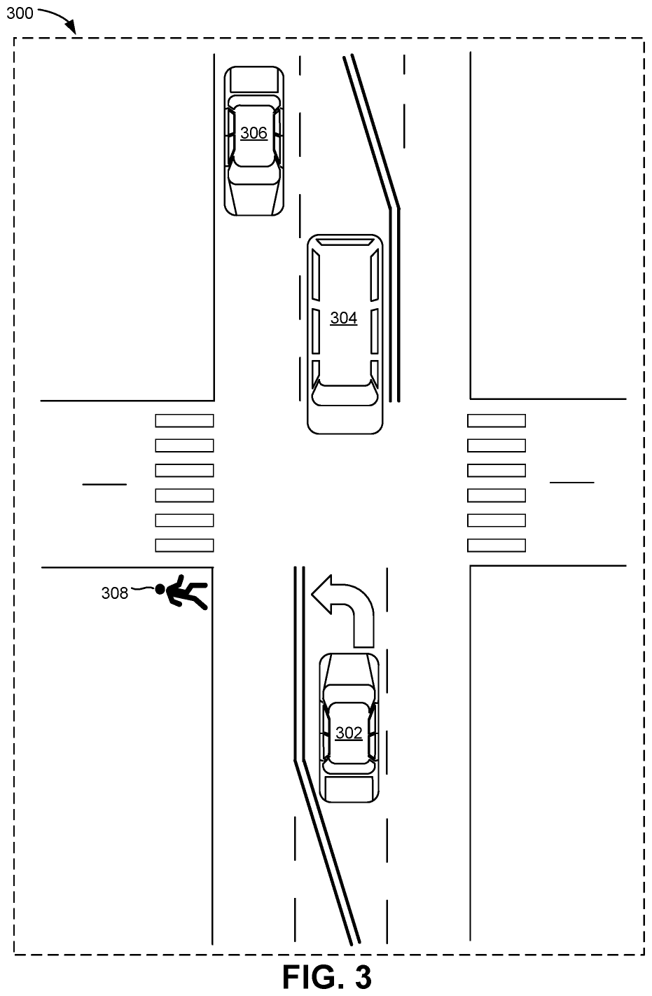

FIG. 3 illustrates an example test scenario 300 executing within a simulation environment. In some aspects, the simulation environment can correspond to AV simulation environment 202. In some cases, the layers and/or parameters of test scenario 300 can be configured using sim configuration tool 206. In some cases, test scenario 300 can be used to test simulated AV 302 in performing an unprotected left turn (e.g., configured test intent).

In some aspects, a sim configuration tool (e.g., sim configuration tool 206) can be used to identify location properties for test scenario 300. As illustrated, the location properties may include an intersection without a traffic light having a left turn lane for AV 302 to turn onto a cross-street having two lanes of traffic. In some cases, the location properties can include a cross-walk that can be used to traverse the cross-street on either side of the intersection. In some aspects, the location properties can include a corresponding left-turn lane for use by oncoming traffic. In some embodiments, a sim configuration tool can identify a geographic location (e.g., an intersection in Miami, Fla.) having the location properties. In some cases, the sim configuration tool can load map data that can be used to generate a simulated environment corresponding to the geographic location.

In some embodiments, a sim configuration tool can be used to configure one or more NPCs within test scenario 300. For example, NPC 304 can correspond to a large van that is placed within the oncoming left turn lane and faces AV 302. In some cases, NPC 304 may be positioned to partially obstruct the view of AV 302. In some examples, NPC 306 can correspond to an oncoming vehicle having the right of way vis-à-vis AV 302. In some instances, sim configuration tool can be used to place NPC 308 corresponding to a pedestrian that may be configured to traverse the cross-street using the crosswalk.

In some aspects, a sim configuration tool can be used to configure intent instructions for one or more of AV 302, NPC 304, NPC 306, and/or NPC 308. As noted above, the test intent for AV 302 can correspond to making an unprotected left turn. In some cases, the test intent for NPC 304 can be to remain stationary throughout the test (e.g., to determine whether AV 302 can complete the turn while having a partially obstructed view). In some aspects, the test intent for NPC 306 can be to cross the intersection safely ahead of AV 302. In some instances, the test intent for NPC 308 (e.g., pedestrian) can be to cross the cross street using the sidewalk.

In some cases, a sim configuration tool can be used to modify one or more layers or parameters associated with test scenario 300. For instance, sim configuration tool 206 can be used to find another intersection having similar location properties (e.g., intersection in Los Angeles, Calif.) for executing the test scenario 300. In some examples, sim configuration tool 206 can be used to modify the start position of AV 302, NPC 304, NPC 306, and/or NPC 308. In some instances, sim configuration tool 206 can be used to modify the intent instructions for one or more NPCs. For example, sim configuration tool 206 can configure AV 306 to make a right turn at the cross street instead of continuing straight through the intersection.

In some examples, sim configuration tool 206 may receive input from simulated AV 302 indicating that the test intent was completed. For example, a planning stack (e.g., planning stack 118) may provide a signal indicating that AV 302 is making a left turn. In some cases, sim configuration tool 206 can determine that test scenario 300 was completed successfully based on data associated with AV 302 (e.g., position, velocity, acceleration, etc.) and/or data associated with any of the NPCs within test scenario 300.

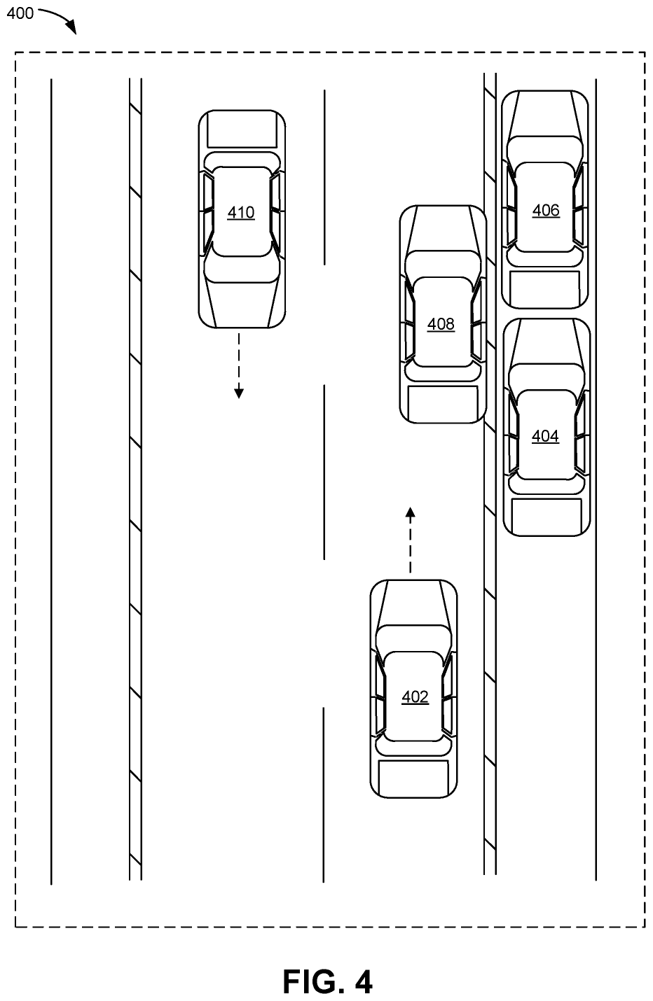

FIG. 4 illustrates an example test scenario 400 executing within a simulation environment. In some aspects, the simulation environment can correspond to AV simulation environment 202. In some cases, the layers and/or parameters of test scenario 400 can be configured using sim configuration tool 206. In some cases, test scenario 400 can be used to test simulated AV 402 in performing a double-parked vehicle maneuver (e.g., configured test intent).

In some aspects, a sim configuration tool (e.g., sim configuration tool 206) can be used to identify location properties for test scenario 400. As illustrated, the location properties may include a two-lane road having a designated parking lane on either side of the road. In some embodiments, a sim configuration tool can identify a geographic location having the location properties. In some cases, the sim configuration tool can load map data that can be used to generate a simulated environment corresponding to the geographic location.

In some embodiments, a sim configuration tool can be used to configure one or more NPCs within test scenario 400. For example, NPC 404 and NPC 406 can correspond to vehicles that are properly parked within the parking lane adjacent to the traffic lane used by AV 402. In some cases, NPC 408 can correspond to a vehicle that is illegally double-parked within the traffic lane and is obstructing the path of AV 402. In some aspects, NPC 410 can correspond to a vehicle that is travelling in the oncoming traffic lane adjacent to AV 402.

In some aspects, a sim configuration tool can be used to configure intent instructions for one or more of AV 402, NPC 404, NPC 406, NPC 408 and/or NPC 410. As noted above, the test intent for AV 402 can correspond to performing a double-parked vehicle maneuver. In some cases, the test intent for NPC 404, NPC 406, and NPC 408 can be to remain stationary throughout the test (e.g., obstructing the path of AV 402). In some aspects, the test intent for NPC 410 can be to continue past AV 402 in the opposite lane of traffic. In some embodiments, test scenario 400 may be successfully completed if AV 402 circumvents AV 408 when it is safe to travel in the lane for oncoming traffic.

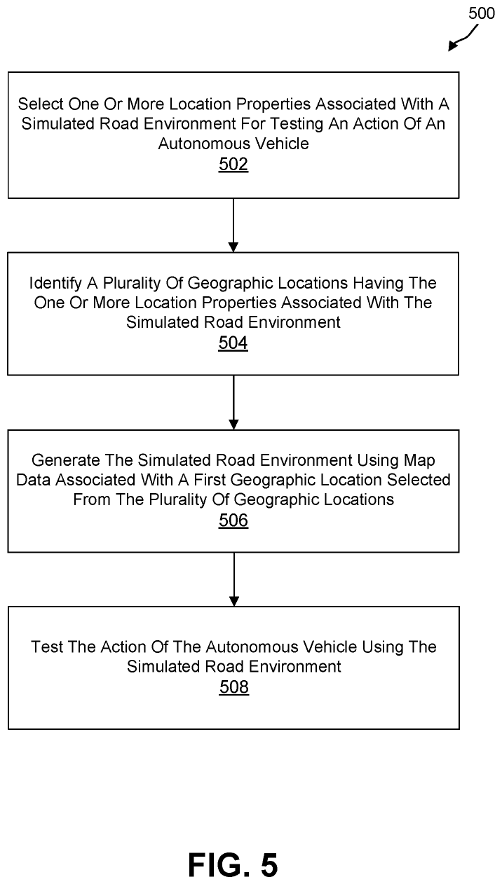

FIG. 5 illustrates a block diagram of an example process 500 for implementing configurable test scenarios for autonomous vehicles. At block 502, the process 500 includes selecting one or more location properties associated with a simulated road environment for testing an action of an autonomous vehicle. For example, sim configuration tool 206 can be used to select one or more location properties associated with a simulated road environment for testing an action of an autonomous vehicle (e.g., AV 102). In some cases, the one or more location properties can include at least one of a number traffic lanes, a traffic signal, a stop sign, a yield sign, a speed limit, a turning lane, a cross street, a bicycle lane, a crosswalk, a street slope, and a street curve.

At block 504, the process 500 includes identifying a plurality of geographic locations having the one or more location properties associated with the simulated road environment. For example, sim configuration tool 206 can use map database 210 to identify a plurality of geographic locations having the one or more location properties (e.g., the number of lanes, traffic light, etc.).

At block 506, the process 500 includes generating the simulated road environment using map data associated with a first geographic location selected from the plurality of geographic locations. For instance, sim configuration tool 206 can be configured to partially generate autonomous vehicle simulation environment 202 using map data (e.g., from map database 210) that is associated with a selected geographic location having the location properties.

At block 508, the process 500 includes testing the action of the autonomous vehicle using the simulated road environment. For instance, AV simulation environment 202 can be used to test the action of the autonomous vehicle. For example, FIG. 3 illustrates a test scenario for testing an unprotected left turn by an AV. In another example, FIG. 4 illustrates a test scenario for testing a double-parked vehicle maneuver by an AV.

In some aspects, the process 500 can include generating a revised simulated road environment using map data associated with a second geographic location selected from the plurality of geographic locations and testing the action of the autonomous vehicle using the revised simulated road environment. For example, sim configuration tool 206 can use map database 210 to identify a second geographic location having the location properties. In some cases, sim configuration tool 206 can modify the test scenario to run the test using map data corresponding to the second geographic location.

In some embodiments, the process 500 can include modifying the simulated road environment to include one or more non-player characters (NPCs), wherein each of the one or more NPCs is associated at least one NPC parameter. For instance, sim configuration tool 206 (and/or NPC AI 208) can be used to modify AV simulation environment 202 to include one or more NPCs (e.g., pedestrians, vehicles, etc.). In some cases, each of the NPCs can be associated with an NPC parameter such as start position, end position, movement speed, etc. In some instances, sim configuration tool 206 may be used to configure intent instructions associated with NPCs.

In some aspects, the process 500 can include receiving an input from the autonomous vehicle indicating performance of the action. For example, sim configuration tool 206 can receive an input from AV software 204 indicating performance of the test intent (e.g., the intended or tested action).

In some implementations, the process 500 can include determining that the autonomous vehicle did not perform the action and modifying at least one simulation parameter associated with the simulated road environment. In some cases, the at least one simulation parameter can include at least one of a traffic parameter, a weather parameter, a time of day parameter, a non-player character (NPC) parameter, and an autonomous vehicle parameter. For example, sim configuration tool 206 can determine that a test scenario did not execute the intended test (e.g., based on data from AV simulation environment 202 and/or AV software 204). In some aspects, sim configuration tool 206 can be used to modify a test scenario by editing one or more layers (e.g., parameters) associated with AV simulation environment 202.

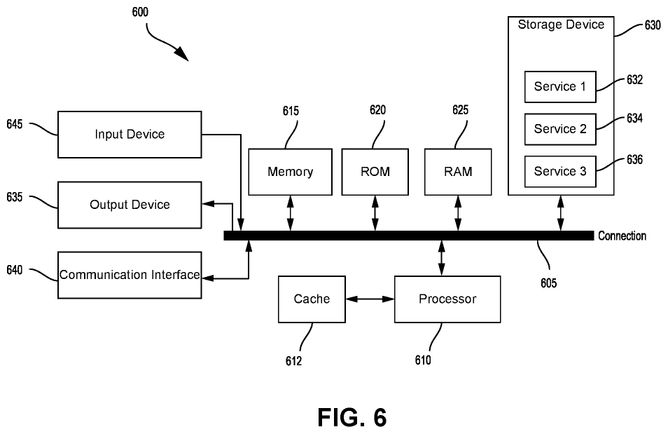

FIG. 6 illustrates an example processor-based system with which some aspects of the subject technology can be implemented. For example, processor-based system 600 can be any computing device making up internal computing device 110, data center 150, client computing device 170, autonomous vehicle simulation environment 202, or any component thereof in which the components of the system are in communication with each other using connection 605. Connection 605 can be a physical connection via a bus, or a direct connection into processor 610, such as in a chipset architecture. Connection 605 can also be a virtual connection, networked connection, or logical connection.

In some embodiments, computing system 600 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 600 includes at least one processing unit (CPU or processor) 610 and connection 605 that couples various system components including system memory 615, such as read-only memory (ROM) 620 and random access memory (RAM) 625 to processor 610. Computing system 600 can include a cache of high-speed memory 612 connected directly with, in close proximity to, or integrated as part of processor 610.

Processor 610 can include any general purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 includes an input device 645, which can represent any number of input mechanisms, such as a microphone for speech, a touch-sensitive screen for gesture or graphical input, keyboard, mouse, motion input, speech, etc. Computing system 600 can also include output device 635, which can be one or more of a number of output mechanisms known to those of skill in the art. In some instances, multimodal systems can enable a user to provide multiple types of input/output to communicate with computing system 600. Computing system 600 can include communications interface 640, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communication interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L5/L #), resistive random-access memory (RRAM/ReRAM), phase change memory (PCM), spin transfer torque RAM (STT-RAM), another memory chip or cartridge, and/or a combination thereof.

Storage device 630 can include software services, servers, services, etc., that when the code that defines such software is executed by the processor 610, it causes the system to perform a function. In some embodiments, a hardware service that performs a particular function can include the software component stored in a computer-readable medium in connection with the necessary hardware components, such as processor 610, connection 605, output device 635, etc., to carry out the function.

As understood by those of skill in the art, machine-learning based classification techniques can vary depending on the desired implementation. For example, machine-learning classification schemes can utilize one or more of the following, alone or in combination: hidden Markov models; recurrent neural networks; convolutional neural networks (CNNs); deep learning; Bayesian symbolic methods; general adversarial networks (GANs); support vector machines; image registration methods; applicable rule-based system. Where regression algorithms are used, they may include including but are not limited to: a Stochastic Gradient Descent Regressor, and/or a Passive Aggressive Regressor, etc.

Machine learning classification models can also be based on clustering algorithms (e.g., a Mini-batch K-means clustering algorithm), a recommendation algorithm (e.g., a Miniwise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim. For example, claim language reciting “at least one of A and B” means A, B, or A and B.

What is claimed is:

1. A system comprising:
one or more processors; and
a computer-readable storage medium coupled to the one or more processors, wherein the computer-readable storage medium comprises instructions that are configured to cause the one or more processors to perform operations comprising:
selecting one or more location properties associated with a simulated road environment for testing an action of an autonomous vehicle;
identifying a plurality of geographic locations having the one or more location properties associated with the simulated road environment;
generating the simulated road environment using map data associated with a first geographic location selected from the plurality of geographic locations; and
testing the action of the autonomous vehicle using the simulated road environment.

2. The system of claim 1, the computer-readable storage medium storing instructions which, when executed by the one or more processors, cause the one or more processors to:
generating a revised simulated road environment using map data associated with a second geographic location selected from the plurality of geographic locations; and
testing the action of the autonomous vehicle using the revised simulated road environment.

3. The system of claim 1, the computer-readable storage medium storing instructions which, when executed by the one or more processors, cause the one or more processors to:
receiving an input from the autonomous vehicle indicating performance of the action.

4. The system of claim 1, the computer-readable storage medium storing instructions which, when executed by the one or more processors, cause the one or more processors to:
modifying the simulated road environment to include one or more non-player characters (NPCs), wherein each of the one or more NPCs is associated with at least one NPC parameter.

5. The system of claim 1, wherein the one or more location properties include at least one of a number traffic lanes, a traffic signal, a stop sign, a yield sign, a speed limit, a turning lane, a cross street, a bicycle lane, a crosswalk, a street slope, and a street curve.

6. The system of claim 1, the computer-readable storage medium storing instructions which, when executed by the one or more processors, cause the one or more processors to:
determining that the autonomous vehicle did not perform the action; and
modifying at least one simulation parameter associated with the simulated road environment.

7. The system of claim 6, wherein the at least one simulation parameter includes at least one of a traffic parameter, a weather parameter, a time of day parameter, a non-player character (NPC) parameter, and an autonomous vehicle parameter.

8. A method, comprising:
selecting one or more location properties associated with a simulated road environment for testing an action of an autonomous vehicle;
identifying a plurality of geographic locations having the one or more location properties associated with the simulated road environment;
generating the simulated road environment using map data associated with a first geographic location selected from the plurality of geographic locations; and
testing the action of the autonomous vehicle using the simulated road environment.

9. The method of claim 8, further comprising:
generating a revised simulated road environment using map data associated with a second geographic location selected from the plurality of geographic locations; and
testing the action of the autonomous vehicle using the revised simulated road environment.

10. The method of claim 8, further comprising:
receiving an input from the autonomous vehicle indicating performance of the action.

11. The method of claim 8, further comprising:
modifying the simulated road environment to include one or more non-player characters (NPCs), wherein each of the one or more NPCs is associated with at least one NPC parameter.

12. The method of claim 8, wherein the one or more location properties include at least one of a number traffic lanes, a traffic signal, a stop sign, a yield sign, a speed limit, a turning lane, a cross street, a bicycle lane, a crosswalk, a street slope, and a street curve.

13. The method of claim 8, further comprising:
determining that the autonomous vehicle did not perform the action; and
modifying at least one simulation parameter associated with the simulated road environment.

14. The method of claim 13, wherein the at least one simulation parameter includes at least one of a traffic parameter, a weather parameter, a time of day parameter, a non-player character (NPC) parameter, and an autonomous vehicle parameter.

15. A non-transitory computer-readable storage medium comprising instructions stored therein, which when executed by one or more processors, cause the one or more processors to perform operations comprising:
select one or more location properties associated with a simulated road environment for testing an action of an autonomous vehicle;
identify a plurality of geographic locations having the one or more location properties associated with the simulated road environment;
generate the simulated road environment using map data associated with a first geographic location selected from the plurality of geographic locations; and
test the action of the autonomous vehicle using the simulated road environment.

16. The non-transitory computer-readable storage medium of claim 15, comprising instructions which, when executed by the one or more processors, cause the one or more processors to perform operations comprising:
generate a revised simulated road environment using map data associated with a second geographic location selected from the plurality of geographic locations; and
test the action of the autonomous vehicle using the revised simulated road environment.

17. The non-transitory computer-readable storage medium of claim 15, comprising instructions which, when executed by the one or more processors, cause the one or more processors to perform operations comprising:
receive an input from the autonomous vehicle indicating performance of the action.

18. The non-transitory computer-readable storage medium of claim 15, comprising instructions which, when executed by the one or more processors, cause the one or more processors to perform operations comprising:
modify the simulated road environment to include one or more non-player characters (NPCs), wherein each of the one or more NPCs is associated with at least one NPC parameter.

19. The non-transitory computer-readable storage medium of claim 15, wherein the one or more location properties include at least one of a number traffic lanes, a traffic signal, a stop sign, a yield sign, a speed limit, a turning lane, a cross street, a bicycle lane, a crosswalk, a street slope, and a street curve.

20. The non-transitory computer-readable storage medium of claim 15, comprising instructions which, when executed by the one or more processors, cause the one or more processors to perform operations comprising:
determine that the autonomous vehicle did not perform the action; and
modify at least one simulation parameter associated with the simulated road environment.
